(19) United States
(12) Patent Application Publication
(10) Pub. No.: US 2026/0298884 A1
(43) Pub. Date: Oct. 1, 2026

(54) METHOD OF APPLYING SIGNAL AMPLIFICATION FOR DRIVING AN ULTRASOUND TRANSDUCER, CORRESPONDING CIRCUIT AND SYSTEM

(71) Applicant: STMicroelectronics International N.V., Geneva (CH)

(72) Inventors: Federico GUANZIROLI, Lentate Sul Seveso (IT); Stefano OTTAVIANI, Magenta (IT)

(73) Assignee: STMicroelectronics International N.V., Geneva (CH)

(21) Appl. No.: 19/578,754

(22) Filed: Mar. 25, 2026

(30) Foreign Application Priority Data
Mar. 31, 2025 (IT) 102025000006753

(51) Int. Cl. G01N 29/32; G01N 29/06; G01N 29/24; G01N 29/34; G01N 29/44; G01N 29/48

(52) U.S. Cl. CPC G01N 29/32; G01N 29/2437; G01N 29/348; G01N 29/4436; G01N 29/4463; G01N 29/48; G01N 29/0672

(57) ABSTRACT

A method includes producing an initial oscillating signal having an initial frequency, applying signal amplification to the initial oscillating signal, providing an output signal as a result. The output signal including first harmonic component at the initial frequency as well as a further signal component at a further frequency. The method includes producing at least one auxiliary oscillating signal having an auxiliary frequency equal to the further frequency, combining the initial oscillating signal and the at least one auxiliary oscillating signal, producing a combined oscillating signal as a result, and applying the signal amplification to the combined oscillating signal. The method includes in response to the at least one auxiliary oscillating signal being an antiphase version of the second harmonic component, producing a combined output signal exempt from the further signal component.

### BACKGROUND

### Technical Field

The description relates to methods and systems for reducing harmonic distortion, for instance in a linear piezoelectric driver.

One or more embodiments may be applied to medical imaging devices such as ultrasound devices, e.g., to increase image quality.

### Description of the Related Art

FIGS. 1 and 2 are diagrams exemplary of a linear driver circuit configured to drive a piezoelectric load and corresponding method.

As exemplified in FIG. 1, a conventional linear driver circuit 10 includes:
a digital sinewave generator 12 configured to produce an initial signal V_{IN}(f₀) having an initial frequency f₀ (e.g., f₀=20 MHz) and initial amplitude |V_{IN}(f₀)|;
a digital-to-analog converter, DAC, circuit block 14 coupled to the digital sinewave generator to receive the initial signal V_{IN}(f0) and to apply digital-to-analog conversion thereto, and
an amplifier circuit block 16 having a (e.g., resistive R or capacitive) feedback branch and coupled to the DAC circuit block 14 to receive the analog-converted initial signal and to apply amplification processing thereto, providing an output voltage Vout(f) having an output frequency based on the initial frequency f₀ and an amplitude which is a multiple of the initial signal amplitude.

As exemplified in FIG. 2, a conventional signal processing method includes multiplying 26 the (analog version of the) initial signal V_{IN}(f₀) generated by the source or generator 12 by the closed loop gain A of the amplifier 16.

Since the amplifier circuit block 16 has non-idealities, there is a distortion signal V_{D}(2f₀) which is superimposed 27 to the multiplied signal, so that the output signal may be expressed as:

$${V}_{OUT} ( f ) = A * {V}_{IN} ( {f}_{0} ) + {V}_{D} ( 2 {f}_{0} ) .$$

Therefore, the distortion signal V_{D} generated due to non-linearities of the error amplifier 16 adds a harmonic distortion contribution inside the system bandwidth.

In ultrasound medical application, it is important to generate a HD2-free TX signal because the second harmonic distortion, generated by the non-linearity response of the medium to the acoustic pressure, is used to detect the medium characteristics and the ability to capture it, is directly correlated to the quality of ultrasound system. Is it known that a medium hit by a signal at an initial frequency f₀, will reflect part of the signal plus a component at twice the initial frequency 2f₀ due to the non-linear elastic response of medium. If the signal impinging on the medium already contains a component at twice the initial frequency, the latter is also reflected by the medium, thereby limiting the imaging resolution because the elastic response of the medium below its amplitude level gets masked.

Therefore, relevant figure of merit for ultrasound application is currently referred to as second harmonic distortion (HD2) factor. The quality of the image detectable by the ultrasound imaging device is proportional to the HD2 factor.

Document US 2019/0190462 A1 discusses a linearization circuit that reduces intermodulation distortion in an amplifier output receives a first signal that includes a first frequency and a second frequency and generates a difference signal having a frequency approximately equal to the difference of the first frequency and the second frequency. The linearization circuit generates an envelope signal based at least in part on a power level of the first signal and adjusts a magnitude of the difference signal based on the envelope signal. When the amplifier receives the first signal at an input terminal and the adjusted signal at a second terminal, intermodulation between the adjusted signal and the first signal cancels at least a portion of the intermodulation products that result from the intermodulation of the first frequency and the second frequency.

Document US 2015/0222119 A1 discusses a system for suppressing signal harmonic distortion caused by a main signal processing device provides processing for an electrical signal containing sine components of multiple frequencies. A post-processor reduces the amplitude of each frequency, relative to other frequencies, as the frequency increases, thus suppressing harmonics, which have higher frequencies than their respective elementary signals. To compensate for frequency distortion caused by the differential frequency suppression in the post-processing stage, a pre-processor provided upstream of the main signal processing device provides frequency-dependent signal processing having a generally opposite effect to that of the post-processor, increasing the amplitude of each frequency of the signal passing through the pre-processor, relative to other frequencies, as the frequency increases. The resulting output signal thus has substantially the same frequency spectrum as the original signal while distortion-causing harmonics are reduced or eliminated.

Known methods to improve HD2 performance can involve increasing the linearity of the operational amplifier. Such a conventional approach presents the drawback of increasing area footprint and energy consumption, as the amplifier includes high voltage capacitors which are non-linear.

### BRIEF SUMMARY

One or more embodiments contribute in overcoming the aforementioned drawbacks.

One or more embodiments may relate to a corresponding circuit and system or

device.

One or more embodiments facilitates reducing area consumption and channel integration.

In doing so, one or more embodiments exDloit the possibility of injecting a pre-distorted waveform based on the fundamental one at the initial frequency plus at least one superposition signal.

One or more embodiments facilitate trimming the HD2 factor.

In one or more embodiments, a method can be executed at application level, e.g., in response to environment changes.

One or more embodiments operate independently from driver architecture.

One or more embodiments facilitate compensating harmonic distortions, e.g., at a frequency integer multiple of the initial frequency or at any given frequency.

In one embodiment, a method includes producing an initial oscillating signal having an initial frequency, applying signal amplification to the initial oscillating signal, providing an output signal as a result. The output signal including first harmonic component at the initial frequency as well as a further signal component at a further frequency. The method includes producing at least one auxiliary oscillating signal having an auxiliary frequency equal to the further frequency, combining the initial oscillating signal and the at least one auxiliary oscillating signal, producing a combined oscillating signal as a result, and applying the signal amplification to the combined oscillating signal. The method includes in response to the at least one auxiliary oscillating signal being an antiphase version of the second harmonic component, producing a combined output signal exempt from the further signal component.

In one embodiment, a circuit includes an initial oscillator circuit block configured to produce an initial oscillating signal having an initial frequency and an amplification circuit block coupled to the initial oscillator circuit block and configured to provide an output signal as a result of applying signal amplification to the initial oscillating signal. The output signal includes a first harmonic component at the initial frequency as well as a further harmonic component at a further harmonic frequency. The circuit includes at least one auxiliary oscillator circuit block configured to produce at least one auxiliary oscillating signal having an auxiliary frequency equal to the further frequency and a combiner node coupled to the initial oscillator circuit block, to the at least one auxiliary oscillator circuit block and to the amplification circuit block. The combiner node is configured to combine the initial oscillating signal and the at least one auxiliary oscillating signal, providing to the amplification circuit block a combined oscillating signal as a result. Applying signal amplification to the combined oscillating signal via the amplification circuit block produces a combined output signal exempt from the further harmonic component in response to the at least one auxiliary oscillating signal being an antiphase version of the further harmonic component.

In one embodiment, a method includes generating a first oscillating signal having a first frequency, generating, with a compensation circuit, a second oscillating signal having a second frequency corresponding to a harmonic of the first frequency, and generating a combined input signal by combining first oscillating signal with the second oscillating signal. The method includes providing the combined input signal to an amplifier, generating, with the amplifier, an output signal by amplifying the input signal, providing the output signal to the compensation circuit in a feedback arrangement, and reducing, in the output signal, a harmonic component of the output signal adjusting the second oscillating signal with the compensation circuit based on the output signal. The harmonic component has the second frequency.

### BRIEF DESCRIPTION OF THE SEVERAL VIEWS OF THE DRAWINGS

One or more embodiments will now be described, by way of non-limiting example only, with reference to the annexed Figures, wherein:

FIGS. 1 and 2 are discussed in the foregoing;

FIG. 3 is a diagram of a method as per the present disclosure;

FIG. 4 is a diagram of principles underlying one or more embodiments;

FIG. 5 is a diagram of a circuit as per the present disclosure;

FIG. 6, including portions a), b) and c), is a diagram exemplary of signals suitable for use in one or more embodiments;

FIG. 7, including portions a) and b), is a diagram of principles underlying one or more embodiments;

FIG. 8 is a diagram exemplary of a phase of initializing auxiliary signals in the method exemplified in FIG. 4;

FIG. 9 is a diagram exemplary of a system as per the present disclosure;

FIG. 10 is a diagram exemplary of a method as per the present disclosure.

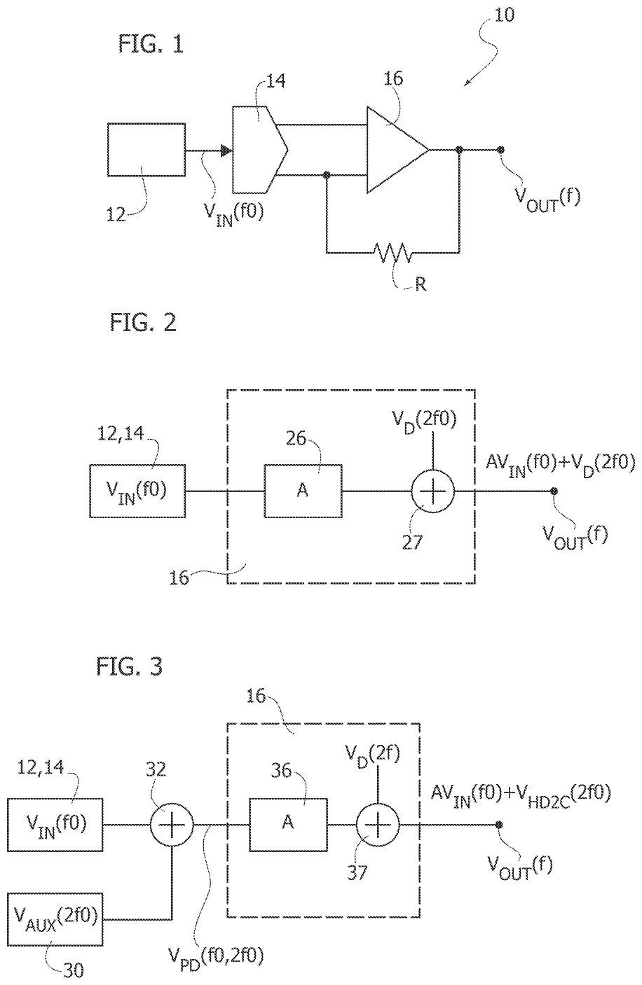

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The references used herein are provided merely for convenience and hence do not define the extent of protection or the scope of the embodiments.

For the sake of simplicity, in the following detailed description a same reference symbol may be used to designate both a node/line in a circuit and a signal which may occur at that node or line.

As exemplified in FIG. 3, an improved signal processing method includes:
generating 30 an auxiliary signal V_{AUX}(2f₀) having a frequency 2f₀ twice the initial frequency f₀ of the initial signal V_{IN}(f₀), and
combining (e.g., superimposing or subtracting) 32 the auxiliary signal V_{AUX}(2f₀) to the (analog version of the) initial signal V_{IN}(f₀) generated by the waveform generator 12, 14 providing a combined input signal as a result;
multiplying 36 the combined input signal by the closed loop gain A of the amplifier 16, providing an amplified combined signal as a result.

Therefore, the amplifier 16 receives a pre-distorted waveform V_{PD}(f₀, 2f₀).

As exemplified in FIG. 3, due to non-linearities in the amplifier circuit block 16, the distortion signal V_{D}(2f₀) is superimposed 37 to the amplified combined signal, so that the output signal may be expressed as:

$${V}_{OUT} ( f ) = A * {V}_{IN} ( {f}_{0} ) + A * {V}_{AUX} ( 2 {f}_{0} ) + {V}_{D} ( 2 {f}_{0} )$$

By appropriately designing the auxiliary input signal V_{AUX} it is possible to delete the spurious harmonic distortion signal V_{D}(2f₀).

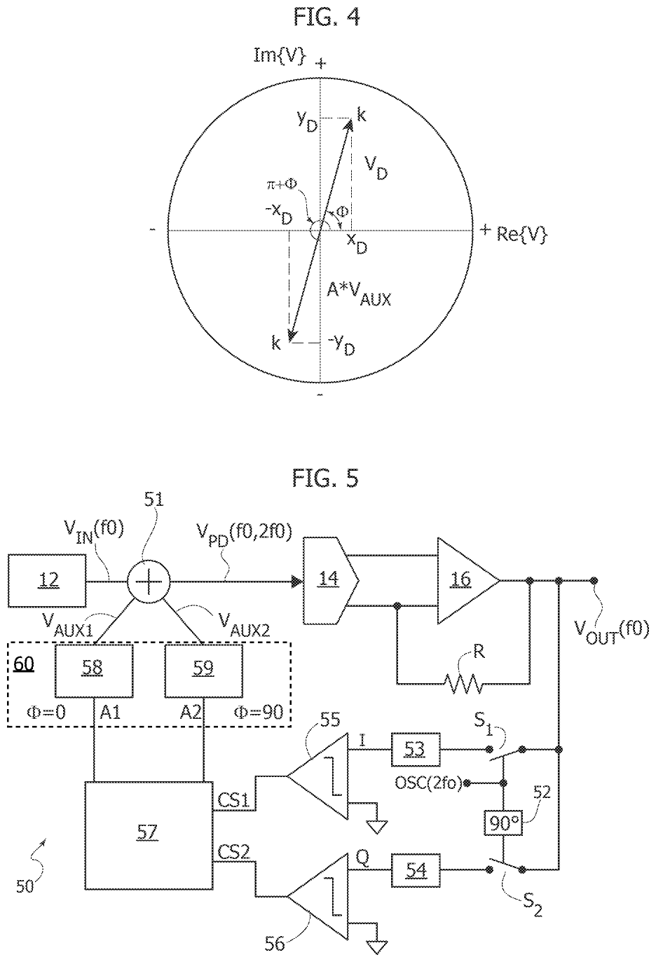

For instance, let's consider the case (illustrated in FIG. 4) in which the distortion signal can be expressed as follows:

$${V}_{D} = A * k * sin ( 2 π ( 2 f ) t + Φ )$$

where A*k are parameters indicative of the amplifier gain.

In such an exemplary case, if the auxiliary input signal is expressed as:

$${V}_{AUX} = k * sin ( 2 π ( 2 f ) t + Φ + π )$$

then it is possible to compensate the harmonic distortion HD2, improving the performance of the actuator 10.

FIG. 4 is a diagram in which the phasors of the distortion signal V_{D} and of the auxiliary signal V_{AUX} are represented on the complex plane, showing the desired scenario in which the phase of the auxiliary signal V_{AUX} has coordinates having a modulus x_{D1}, y_{D1} and opposite sign with respect to those of the (pre-amplification) distortion signal on both the real and imaginary axes of the complex plane, e.g., V_{D}=A*V_{AUX}=x_{D}+i_{YD}; V_{AUX}=(−x_{D}−jy_{D})/A.

As exemplified herein, the method includes:
injecting a pre-distorted waveform V_{PD} based on the initial signal V_{IN}(f₀) at the initial frequency f₀ plus at least one auxiliary signal V_{AUX}(2f₀) at an auxiliary frequency 2f₀ twice the initial frequency f₀;
removing a higher harmonic component V_{D} from the output voltage V_{OUT} thanks to setting the amplified at least one auxiliary signal AV_{AUX}(2f₀) with same amplitude and opposite phase respect to the higher harmonic component V_{D}; and/or
performing a start-up procedure by providing a down-conversion mixer with an oscillator set at the higher harmonic frequency 2f₀ to move the target component to DC (I/Q components DC values are the magnitude of the two vector projections on the axes representing the amplitude multiplied by sine and cosine, they are used to measure phase and amplitude of the higher harmonic component);

As exemplified herein, the proposed solution involves a measure of the parameters (magnitude and phase) of the phasor of the distortion signal V_{D} in order to generate 30 the auxiliary signal V_{AUX}, imposing the condition that V_{D}=A*V_{AUX}.

In order to perform such a measurement, the method may envisage using a start-up procedure, as discussed in the following.

FIG. 5 is a diagram exemplary of an improved linear piezoelectric driver circuit 50 as per the present disclosure.

As exemplified in FIG. 5, the circuit 50 includes:
a combiner node 51 interposed a digital (e.g., sinewave) generator 12 configured to produce the initial signal V_{IN}(f₀) and the DAC conversion circuit block 14, the combiner node 51 providing the combined signal V_{PD}(f₀, 2f₀) as a result;
a down conversion mixer 52, 53, 54, S1, S2 coupled to the output node of the amplifier to receive the output signal V_{OUT} including the distortion signal V_{D} component therefrom, the down conversion mixer 52, 53, 54, S1, S2 configured to down-convert (the distortion signal V_{D} part of) the output signal V_{OUT} (e.g., from twice the initial frequency f₀ to DC), providing a set of I/Q signals indicative of a magnitude of the phasor coordinates on the complex plane axes (x_{D} and y_{D}, as they represent the amplitude multiplied by sine and cosine, respectively);
a set of (e.g., two) comparators 55, 56 coupled to the down conversion mixer 52, 53, 54, S1, S2 to receive the I/Q projections therefrom, the set of comparators configured to check the sign of the received signals by comparing them with a (e.g., programmable) threshold (e.g., at ground level GND), the set of comparators configured to issue a respective set of logic signals CS1, CS2 having a first logic value (e.g., “0” or “false”) in response to detecting a negative I/Q sign and having a second logic value (e.g., “1” or “true”) in response to detecting a positive I/Q sign;
a control circuit 57 coupled to the set of comparators 55, 56 to receive the set of logic signals CS1, CS2 and coupled to a set of digital generators 60 (e.g., including two generators 58, 59) to drive generation of a set of auxiliary signals V_{AUX1}, V_{AUX2} to perform (e.g., according to a successive-approximation algorithm) iterative compensation of the distortion signal V_{D}.

It is noted that, while the exemplary circuit diagram exemplified in FIG. 5 includes two auxiliary generators 58, 59, such a number of generators is purely exemplary and in no way limiting. In one or more embodiments, the set of generators 60 includes notionally any number of signal generators. For instance, the set of generators 60 includes one auxiliary signal generator 60 configured to produce one auxiliary signal V_{AUX} as the quadratic sum of first V_{AUX1} and second V_{AUX2} auxiliary signals.

It is noted that one or more embodiments are discussed herein mainly with reference to a successive-approximation method for measuring the distortion signal V_{D}, being otherwise understood that such a measuring method is purely exemplary and non-limiting. One or more embodiments may employ notionally any kind of “search” or “measurement” method for the distortion component.

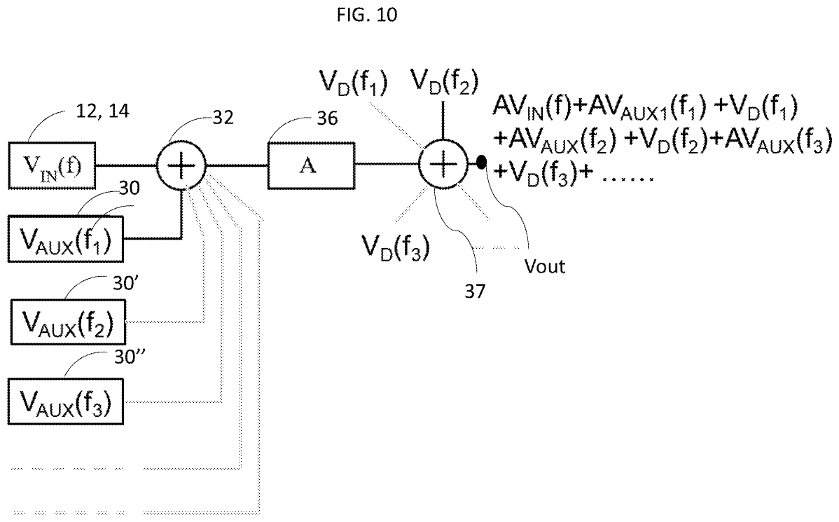

As exemplified in FIGS. 5 and 10, it is possible to use more than one auxiliary signal to pre-distort the input signal for the amplifier 16.

For instance, FIG. 5 illustrates an exemplary scenario using one sinewave as a first auxiliary signal V_{AUX1} and a second sinewave in quadrature with the first as the second auxiliary signal V_{AUX2}, with the control circuit 57 configured to drive (at least in terms of amplitude and phase) both signal generators V_{AUX1}, V_{AUX2}.

As exemplified in FIG. 5, the auxiliary signals in the set of auxiliary signals V_{AUX1}, V_{AUX2} is provided at the combiner node 51 to be superimposed to the initial signal V_{IN}, providing the combined signal which is amplified once again 16 to perform a subsequent iteration of the down-conversion mixing, until reaching a dynamic equilibrium condition at a desired system resolution.

As exemplified in FIGS. 3 and 5, a method of performing a startup phase for the compensation circuit 50 as per the present disclosure includes:
applying down-conversion mixing 52, 53, 54, S1, S2 obtaining a down-converted version of the output signal V_{OUT} including I/Q components indicative of the magnitude of the phasor projections on the complex plane axes (x_{D} and y_{D});
detecting 55, 56 respective signs of the I/Q components and providing respective logic signals CS1, CS2,
setting (e.g., amplitude and phase) values 57 for generating 58, 59 a set of auxiliary signals AUX1, AUX2 and combining (e.g., linearly) 51 the generated auxiliary signals AUX1, AUX2 to the initial signal V_{IN}(f₀), providing a combined signal V_{PD} to the amplifier 16;
iterating the algorithm to generate stimulus for a next tentative iteration, stopping the iteration when the system resolution is reached.

It is possible to express the set of auxiliary signals AUX1, AUX2 provided by generators 58, 59 as:

$${V}_{AUX 1} = - {Y}_{D} / A sin ( 2 pi * 2 f 0 * t )$$

$${V}_{AUX 2} = - {X}_{D} / A sin ( 2 pi * 2 f 0 * t + π / 2 )$$

In an alternative scenario, it may be possible to use a single auxiliary generator 60 to produce a single auxiliary signal AUX which may be expressed as:

$${V}_{AUX} = sqrt ( {AUX 1}^{2} + {AUX 2}^{2} ) = k / A sin ( 2 π * 2 f 0 * t + π + Φ 1 )$$

As exemplified in FIG. 5, the down-conversion mixer 52, 53, 54, S1, S2 includes:
a phase-shifter 52 configured to apply quadrature (e.g.,) 90° phase shifting to the output signal V_{OUT};
a set of low-pass filters 53, 54 configured to apply low-pass filtering to the mixer output signal, providing filtered signal components I/Q,
an oscillator input node OSC configured to receive (from an oscillator per se known) an oscillator signal OSC at frequency 2f₀ twice the initial frequency f₀.

As exemplified in FIG. 5, a set of switches S1, S2 is interposed the input nodes of the low-pass filters and the output node V_{OUT} of the circuit 50 perform signal mixing. Optionally, they can also be operated to decouple the processing chain once the system resolution is reached for the value of the auxiliary signals V_{AUX1}, V_{AUX2}.

For instance, the method includes:
at a beginning of a startup phase, the switches S1, S2 are operated (e.g., alternatingly turned ON and OFF) in order to measure the distortion V_{D} and find the value for the auxiliary signal V_{AUX};
optionally, once the distortion factor can be deemed compensated for the resolution of the system, the switches are opened in order to fix the steady-state value of the auxiliary signal V_{AUX}.

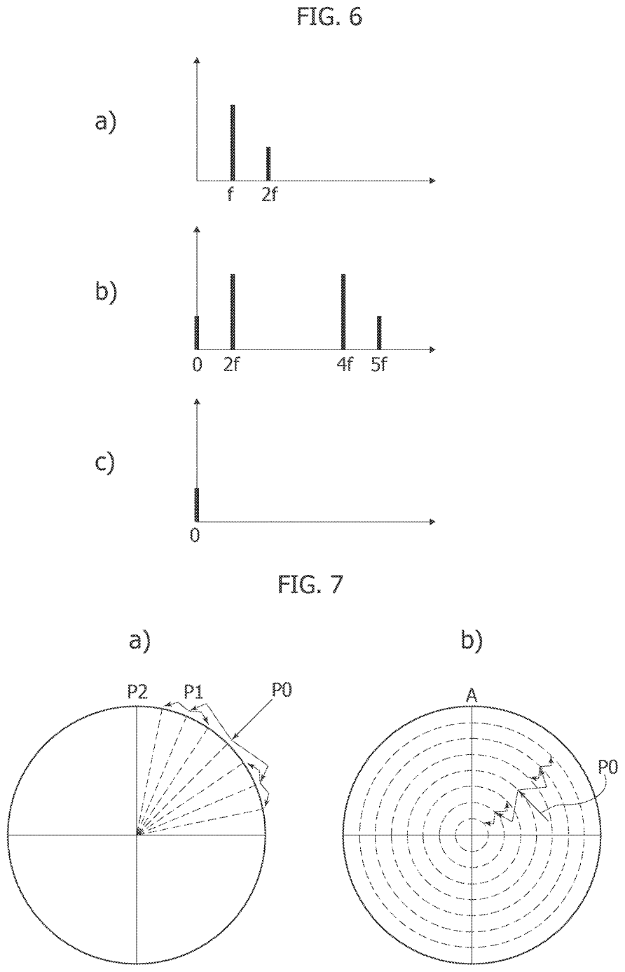

Portion a) of FIG. 6 is a plot (amplitude in arbitrary units on the ordinate axis, frequency in Hz on the horizontal axis) of the spectral components of the output signal V_{OUT}. As exemplified in portion a) of FIG. 6, initially the output signal includes both the signal at the fundamental frequency f₀ and the harmonic distortion V_{D} at twice the initial frequency 2f₀.

Portion b) of FIG. 6 is a plot (amplitude in arbitrary units on the ordinate axis, frequency in Hz on the horizontal axis) of the spectral components of the output signal V_{OUT} mixed with the signal from the oscillator OSC at twice the initial frequency f₀. As exemplified in portion b) of FIG. 6, various spectral components are generated as a result of mixing. For instance, a DC component is generated as a result of mixing, where the DC component includes the information about phase and amplitude of the harmonic distortion Vd.

Portion c) of FIG. 6 is a plot (amplitude in arbitrary units on the ordinate axis, frequency in Hz on the horizontal axis) of the spectral components of the I/Q components of the mixed signal after low-pass filtering 53, 54. As exemplified in portion c) of FIG. 6, only the DC component remains after filtering.

As exemplified in FIG. 7, the correction algorithm acts by driving the generators 58, 59 to vary the amplitude of the auxiliary signals V_{AUX1}, V_{AUX2} until reaching a point in which a change in the auxiliary signals does not lead to a reduction of the HD2 factor of the output signal V_{OUT}.

Portion a) of FIG. 7 is an exemplary diagram exemplary of principles underlying embodiments in finding the phase of the phasors of the set of auxiliary signals V_{AUX1}, V_{AUX2} or equivalently of a single auxiliary signal V_{AUX} as the vector sum of the two V_{AUX1}, V_{AUX2} while portion b) of FIG. 7 is an exemplary diagram exemplary of principles underlying embodiments in finding the amplitude of the phasor of the auxiliary signal V_{AUX} to compensate the distortion V_{D}, e.g., using a SAR algorithm (per se known).

As exemplified in FIG. 7, the iterative method as per the present disclosure includes:
at the beginning of the startup phase, initializing to zero the value of the auxiliary signal amplitude in order to detect the amplitude and phase of the distortion signal Vd to compensate;
after having determined a quadrant in which the distortion signal Vd lies, setting an initial value for the phase of the auxiliary signal phasor V_{AUX} can be set equal to the middle of a first quadrant of the complex plan, e.g., P0=π/4 while the amplitude of the auxiliary phasor may be initiated to a value A0 equal to half an amplification gain G;
at the subsequent iteration, the exploration continues by moving to the center of one of the two halves of the initial angle or amplitude (plus or minus a constant angle, as discussed in the following), e.g., P1=(π/8,A/4);
the search for the equilibrium value of the auxiliary signal continues by halving the search interval at each iteration, e.g., P3=(π/16,A/8).

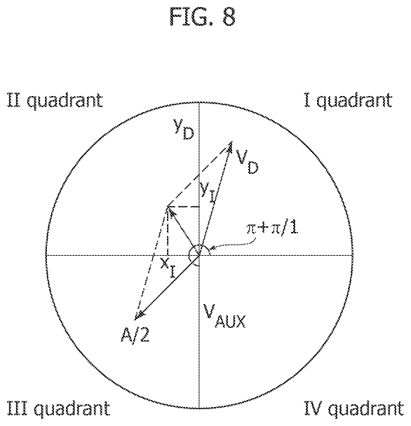

FIG. 8 is a diagram exemplary of a first iteration of the control logic 57 in the following hypothetical scenario:

The distortion signal V_{D} has initial coordinates falling in a first (e.g., positive) quadrant of the complex plane, e.g., V_{D}=x_{D}+iy_{D};

It is the first iteration of the method so that the control logic 57 has to assign values to the initial coordinates of the auxiliary signal, e.g., V_{AUX}−x₁+iy₁.

In the exemplary scenario exemplified in FIG. 8, the initial phase of V_{AUX} is based on the feedback logic signals CS1, CS2 coming from the comparators 55, 56. For instance:
in a first case in which both the first comparator signal CS1 and the second comparator signal CS2 are issued by comparators 55, 56 having the first logic value (e.g., “1” or “true”), (e.g., [CS1, CS2]=(1,1)), the control logic 57 interprets such signals as indicative of the fact that the phasor of the distortion signal V_{D} lies in I quadrant (e.g., positive real and imaginary parts) of the complex plane; therefore, as the control logic 57 drives the digital generator(s) 58, 59 to produce auxiliary signal(s) having a phasor that lies in the opposite quadrant, the initial conditions for the auxiliary signal will go in the direction of having it lie in the III quadrant (negative real and imaginary parts) of the complex plane, e.g., |V_{AUX}|=A/2; Φ_{AUX}=π+π/4;
in a second case in which the first comparator signal CS1 is issued by the first comparator 55 having the second logic values (e.g., “0” or “false”) while the second comparator signal CS2 is issued by the second comparator signal CS2 having the first logic value, (e.g., [CS1, CS2]=(0,1)), the control logic 57 interprets such signals as indicative of the fact that the phasor of the distortion signal V_{D} lies in II quadrant (e.g., positive real part and negative imaginary part) of the complex plane; therefore, as the control logic 57 drives the digital generator(s) 58, 59 to produce auxiliary signal(s) having a phasor that lies in the opposite quadrant, the initial conditions for the auxiliary signal will go in the direction of having it lie in the II quadrant (negative real part and positive imaginary part) of the complex plane, e.g., |V_{AUX}|=A/2; Φ_{AUX}=3/π+π/4;
in a third case in which both the first comparator signal CS1 and the second comparator signal CS2 are issued having the second logic value, (e.g., [CS1, CS2]=(0,0)), the control logic 57 interprets such signals as indicative of the fact that the phasor of the distortion signal V_{D} lies in III quadrant (e.g., negative real and imaginary parts) of the complex plane; therefore, as the control logic 57 drives the digital generator(s) 58, 59 to produce auxiliary signal(s) having a phasor that lies in the opposite quadrant, the initial conditions for the auxiliary signal will go in the direction of having it lie in the I quadrant (positive real and imaginary parts) of the complex plane, e.g., |V_{AUX}|=A/2; Φ_{AUX}=π/4;
in a fourth case in which the first comparator signal CS1 is issued by the first comparator 55 having the first logic value while the second comparator signal CS2 is issued by the second comparator signal CS2 having the second logic value, (e.g., [CS1, CS2]=(1,0)), the control logic 57 interprets such signals as indicative of the fact that the phasor of the distortion signal V_{D} lies in IV quadrant (e.g., positive real part and negative imaginary part) of the complex plane; therefore, as the control logic 57 drives the digital generator(s) 58, 59 to produce auxiliary signal(s) having a phasor that lies in the opposite quadrant, the initial conditions for the auxiliary signal will go in the direction of having it lie in the IV quadrant (positive real part and negative imaginary part) of the complex plane, e.g., |V_{AUX}|=A/2; Φ_{AUX}=π+π/4;

As discussed in the foregoing, at subsequent iterations the control logic 57 updates the values of amplitude and phase (or real and imaginary parts) of the auxiliary signal(s) according to the rules summarized in Table I in the following.

TABLE I
Control Logic Table of Truth of the
Control Logic for First Case Scenario

| Complex plane quadrant | [CS1, CS2] | Action by control signal |
|---|---|---|
| V_{D} in I quadrant | (1, 1) | Increase \|V_{AUX}\| |
| V_{D} in I quadrant | (1, 0) | Decrease Φ_{AUX} |
| V_{D} in I quadrant | (0, 1) | Increase Φ_{AUX} |
| V_{D} in I quadrant | (0, 0) | Decrease \|V_{AUX}\| |
| V_{D} in II quadrant | (1, 1) | Decrease Φ_{AUX} |
| V_{D} in II quadrant | (1, 0) | Decrease \|V_{AUX}\| |
| V_{D} in II quadrant | (0, 1) | Increase \|V_{AUX}\| |
| V_{D} in II quadrant | (0, 0) | Increase Φ_{AUX} |
| V_{D} in III quadrant | (1, 1) | Decrease \|V_{AUX}\| |
| V_{D} in III quadrant | (1, 0) | Increase Φ_{AUX} |
| V_{D} in III quadrant | (0, 1) | Decrease Φ_{AUX} |
| V_{D} in III quadrant | (0, 0) | Increase \|V_{AUX}\| |
| V_{D} in IV quadrant | (1, 1) | Increase Φ_{AUX} |
| V_{D} in IV quadrant | (1, 0) | Increase \|V_{AUX}\| |
| V_{D} in IV quadrant | (0, 1) | Decrease \|V_{AUX}\| |
| V_{D} in IV quadrant | (0, 0) | Decrease Φ_{AUX} |

Using the successive-approximation method discussed in the foregoing, the auxiliary signal(s) V_{AUX}=V_{AUX}1+i_{VAUX2} converges to final values which can be expressed x_{F}+iy_{F}=(−x_{D}−iy_{D})/A that is with the same amplitude of distortion before amplification V_{D}/A but opposite phase. For instance, the final values match the resolution on phase and amplitude that the system 50 is configured to reproduce.

The following Table II summarizes an exemplary case including five iterations of the method which is described by listing the feedback signal values as well as the auxiliary amplitude and phase values for each iteration, in the hypothesis that the distortion signal can be expressed as |V_{D}|=7A/8; Φ_{D}=7π/16.

TABLE II
Summary of the Values of Different Parameters in a 5-Step
Iteration of the Method as per the Present Disclosure

| Iteration no. | [CS1, CS2] | \|V_{AUX}\| | Φ_{AUX} |
|---|---|---|---|
| 0 | —, — | A/2 | π/4 |
| 1 | (1, 1) | A/2 | π/4 + π |
| 2 | (0, 1) | A/2 | π + 3/8π |
| 3 | (1, 1) | ¾*A | π + 3/8π |
| 4 | (0, 1) | ¾*A | π + 7π/16 |
| 5 | (1, 1) | ⅞*A | π + 7π/16 |

Inventors have observed that the solution discussed in the foregoing with reference to second harmonic distortion can be applied mutatis mutandis to compensating distortion signals at any given frequency.

As exemplified in FIG. 10, the distortion signal Vd includes a set of distortion components that can have a frequency twice the initial frequency but also other or alternative frequency values f1, f2, f3 . . .

For instance:
a first distortion component Vd(f1) can have a first distortion frequency f1 at twice the initial frequency f₀;
a second distortion component Vd(f2) can have a second distortion frequency f2 that is an integer N multiple greater than two (e.g., N>=2) of the initial frequency f₀;
a third distortion component Vd(f3) can have a third distortion frequency f3 that has no specific relation to the initial frequency f₀.

As exemplified in FIG. 10, the method envisages using a set of auxiliary frequency generators 30, 30′, 30″ and to use each auxiliary frequency generator in the set of auxiliary frequency generators 30, 30′, 30″ to compensate at least one respective distortion signal component Vd(f1), Vd(f2), Vd(f3).

For instance:
a first auxiliary signal generator 30 is configured to produce a first auxiliary signal Vaux(f1) at a first auxiliary frequency f1 equal to the first distortion frequency f1 of the first distortion component Vd(f1) (e.g., f1=2f0);
a second auxiliary signal generator 30′ is configured to produce a second auxiliary signal Vaux(f2) at a second auxiliary frequency f2 equal to the second distortion frequency f2 of the second distortion component Vd(f2) (e.g., f2=Nf0);
a third auxiliary signal generator 30″ is configured to produce a third auxiliary signal Vaux(f3) at a third auxiliary frequency f3 equal to the third distortion component Vd(f3) (with f3 having a given value).

As exemplified in FIG. 10, the method includes:
injecting a set of pre-distorted waveforms as the sum of initial signal V_{IN}(f₀) plus the set of auxiliary signals V_{AUX}(f₁), V_{AUX}(f₂), V_{AUX}(f₃) whose properties are defined based on the distortion components Vd(f1), Vd(f2), Vd(f3);
as a result of the superposition, both the initial signal and the auxiliary signals are amplified and summed to the distortion components;
as a result of generating the auxiliary signals according to the discussion in the foregoing, when AV_{AUX}=A (Vaux1+Vaux2+Vaux3) has same amplitude and opposite phase respect to V_{D}=Vd(f1)+Vd(f2)+Vd(f3), the output signal Vout can be expressed as:

$${V}_{out} = {AV}_{IN} ( f ) + {AV}_{AUX 1} ( {f}_{1} ) + {V}_{D} ( {f}_{1} ) + {AV}_{AUX} ( {f}_{2} ) + {V}_{D} ( {f}_{2} ) + {AV}_{AUX} ( {f}_{3} ) + {V}_{D} ( {f}_{3} ) + …$$

where

$${V}_{D} ( f 1 ) = k * sin ( 2 π ( {f}_{1} ) t + Φ ) ;$$

$${V}_{D} ( f 2 ) = k * sin ( 2 π ( {f}_{2} ) t + Φ ) ;$$

$${V}_{D} ( f 3 ) = k * sin ( 2 π ( {f}_{3} ) t + Φ ) and$$

$${V}_{AUX} ( f 1 ) = k / A * sin ( 2 π ( {f}_{1} ) t + Φ + π ) ;$$

$${V}_{AUX} ( f 2 ) = k / A * sin ( 2 π ( {f}_{2} ) t + Φ + π ) ;$$

$${V}_{AUX} ( f 3 ) = k / A * sin ( 2 π ( {f}_{3} ) t + Φ + π )$$

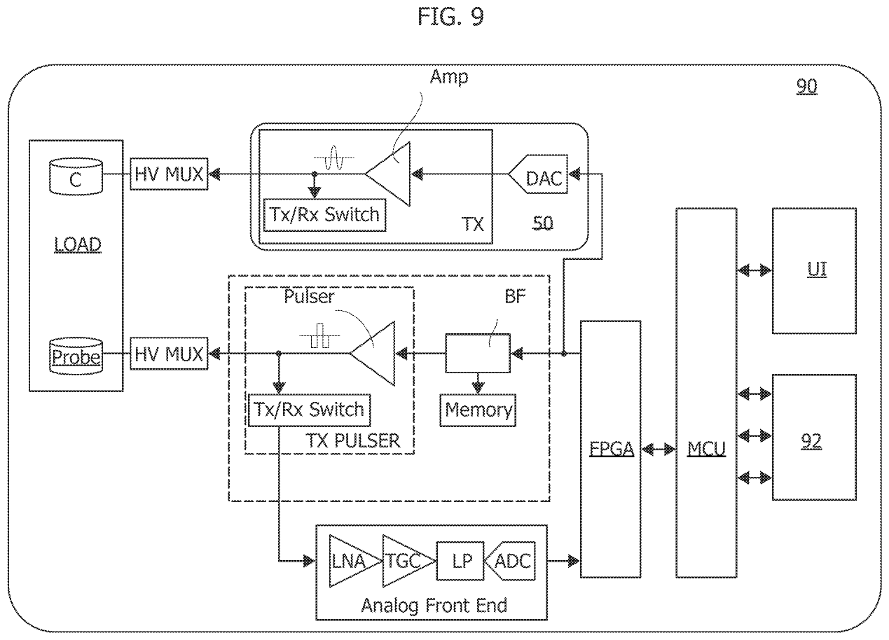

As exemplified in FIG. 9, an ultrasound imaging system 90 includes:
a user interface UI configured to facilitate the user in acquiring the imaging signal; for instance, the UI includes HDMI/VIDEO display protection, GPIO protection for keyboard/trackboard, audio amplifier for a speaker;
connectivity circuitry 92 configured to transmit and receive signals via connectivity networks (per se known) such as Wi-Fi, Ethernet and so on;
a microcontroller unit MCU coupled to the user interface UI and the connectivity circuitry 92,
signal processing circuitry, such as a field-programmable gate array, FPGA, coupled to the microcontroller unit MCU;
a pulser or a linear transmitter equipped with the circuit 50 as per the present disclosure to drive a first LOAD C, the pulser or linear transmitter further coupled to the signal processing circuitry FPGA and the microcontroller unit MCU, where the pulser or linear transmitter is configured to drive a pulsed Probe LOAD, (in a manner per se known).

In a first example, a method includes:
producing an initial oscillating signal having an initial frequency;
applying signal amplification to the initial oscillating signal, providing an output signal as a result, the output signal including a first harmonic component at the initial frequency as well as a further signal component at a further frequency;
producing at least one auxiliary oscillating signal having an auxiliary frequency equal to the further frequency;
combining the initial oscillating signal and the at least one auxiliary oscillating signal, producing a combined oscillating signal as a result, and
applying the signal amplification to the combined oscillating signal, and
in response to the at least one auxiliary oscillating signal being an antiphase version of the second harmonic component, producing a combined output signal exempt from the further signal component.

In a second example, the further frequency of the further signal component is equal to an integer multiple, preferably twice, the initial frequency so that the at least one auxiliary oscillating signal has the auxiliary frequency equal to the integer multiple, preferably twice, of the initial frequency.

In a third example, the further frequency of the further signal component is equal to a linear combination of integer multiples of the initial frequency so that the at least one auxiliary oscillating signal has the auxiliary frequency equal to a linear combination of integer multiples of the initial frequency.

In a fourth example, the combined output signal is exempt from the further signal component in response to an auxiliary amplitude of the at least one auxiliary oscillating signal being equal to an amplitude of the further signal component as well as in response to an auxiliary phase of the at least one auxiliary oscillating signal being equal and opposite to a phase of the further harmonic component.

In a fifth example, the method includes iteratively adjusting the at least one auxiliary oscillating signal from initial values until reaching the antiphase version of the further signal component.

In a sixth example, iteratively adjusting the at least one auxiliary oscillating signal includes:
initializing an auxiliary amplitude of the at least one auxiliary oscillating signal to an initial amplitude, preferably equal to zero;
detecting the further harmonic component in the output signal;
setting an auxiliary amplitude of the at least one auxiliary oscillating signal to an initial amplitude, preferably equal half the amplification gain;
initializing an auxiliary phase of the at least one auxiliary oscillating signal to an initial phase value, preferably equal to 45°;
performing a comparison of the auxiliary signal and the second harmonic signal, and
iteratively adjusting the auxiliary amplitude and/or the auxiliary phase based on the comparison until reaching the antiphase version of the second harmonic component.

In a seventh example, the method includes applying down-conversion mixing to the output signal using a local oscillator signal at a frequency equal to the further frequency and a quadrature phase shifter as well as applying low-pass filtering, producing a first and a second mixed signal components in quadrature therebetween as a result, the first and second mixed signal components each including a respective DC component;
performing a first comparison of the first mixed signal DC component with a threshold, providing a first logic signal having a first, resp. second, logic value in response to the first mixed signal DC component exceeding, resp. failing to exceed, the threshold;
performing a second comparison of the second mixed signal DC component with the threshold, providing a second logic signal having a first, resp. second, logic value in response to the second mixed signal DC component exceeding, resp. failing to exceed, the threshold;
iteratively adjusting the auxiliary amplitude and/or the auxiliary phase based on the comparison including adding or subtracting a fraction of the initial auxiliary amplitude and/or of the initial auxiliary phase, preferably via a successive-approximation controller, until reaching the antiphase version of the second harmonic component.

In an eighth example, the method includes:
producing a plurality of auxiliary oscillating signals each having an auxiliary frequency equal to the further frequency;
combining the initial oscillating signal and the plurality of auxiliary oscillating signals, producing a combined oscillating signal as a result;
applying the signal amplification to the combined oscillating signal, and
in response to a combination of one auxiliary oscillating signals in the plurality of auxiliary oscillating signals being equal to an antiphase version of the second harmonic component, producing a combined output signal exempt from the second harmonic component.

In a ninth example, a circuit includes:
an initial oscillator circuit block configured to produce an initial oscillating having an initial frequency;
an amplification circuit block coupled to the initial oscillator circuit block and configured to provide an output signal as a result of applying signal amplification to the initial oscillating signal, the output signal including a first harmonic component at the initial frequency as well as a further harmonic component at a further harmonic frequency;
at least one auxiliary oscillator circuit block configured to produce at least one auxiliary oscillating signal having an auxiliary frequency equal to the further frequency;
a combiner node coupled to the initial oscillator circuit block, to the at least one auxiliary oscillator circuit block and to the amplification circuit block, the combiner node configured to combine the initial oscillating signal and the at least one auxiliary oscillating signal, providing to the amplification circuit block a combined oscillating signal as a result,
wherein applying signal amplification to the combined oscillating signal via the amplification circuit block produces a combined output signal exempt from the further harmonic component in response to the at least one auxiliary oscillating signal being an antiphase version of the further harmonic component.

In a tenth example, the combined output signal is exempt from the further harmonic component in response to an auxiliary amplitude of the at least one auxiliary oscillating signal being equal to a further harmonic amplitude of the further harmonic component as well as of an auxiliary phase of the at least one auxiliary oscillating signal being equal and opposite to a further harmonic phase of the further harmonic component.

In an eleventh example, the circuit includes signal processing circuitry configured to iteratively adjust the at least one auxiliary oscillating signal from initial values until reaching the antiphase version of the further harmonic component.

In a twelfth example, the signal processing circuitry is selectively couplable to the output signal and is configured to:
detect the further harmonic signal in the output signal;
initialize an auxiliary amplitude of the at least one auxiliary oscillating signal to an initial amplitude value, preferably equal to half an amplification gain of the amplification circuit block;
initialize an auxiliary phase of the at least one auxiliary oscillating signal to an initial phase value, preferably equal to 45°;
perform a comparison of the auxiliary signal and the second harmonic signal, and
drive the at least one auxiliary oscillator circuit block to iteratively adjust the auxiliary amplitude and/or the auxiliary phase based on the comparison until reaching the antiphase version of the further harmonic component.

In a thirteenth example, the circuit includes:
a down-conversion mixer circuit block configured to apply down-conversion mixing to the output signal using a local oscillator signal at twice the initial frequency and a quadrature phase shifter as well as applying low-pass filtering, producing a first and a second mixed signal components in quadrature therebetween as a result, the first and second mixed signal components each including a respective DC component;
a first comparator circuit block coupled to the down-conversion mixer circuit block and configured to perform a first comparison of the first mixed signal DC component with a threshold, providing a first logic signal having a first, resp. second, logic value in response to the first mixed signal DC component exceeding, resp. failing to exceed, the threshold;
a second comparator circuit block coupled to the down-conversion mixer circuit block and configured to perform a second comparison of the second mixed signal DC component with the threshold, providing a second logic signal having a first, resp. second, logic value in response to the second mixed signal DC component exceeding, resp. failing to exceed, the threshold;
control circuitry configured to drive the at least one auxiliary oscillator circuit block to iteratively adjust the auxiliary amplitude and/or the auxiliary phase based on the comparison including adding or subtracting a fraction of the initial auxiliary amplitude and/or of the initial auxiliary phase, preferably via a successive-approximation controller, until reaching the antiphase version of the further harmonic component.

In a fourteenth example:
the at least one auxiliary oscillator circuit block includes a plurality of auxiliary oscillator circuit block configured to produce a plurality of auxiliary oscillating signals each having an auxiliary frequency;
the combiner node is configured to combine the initial oscillating signal and the plurality of auxiliary oscillating signals, producing the combined oscillating signal as a result, and
wherein applying signal amplification to the combined oscillating signal via the amplification circuit block produces a combined output signal exempt from the further harmonic component in response to a combination of one auxiliary oscillating signals in the plurality of auxiliary oscillating signals being equal to an antiphase version of the further harmonic component.

In a fifteenth example, a device includes:
at least one circuit according to any one of the aforementioned examples;
at least one ultrasound transducer circuit configured to be driven to produce ultrasound waves via the at least one circuit, preferably including a medical imaging device.

It will be otherwise understood that the various individual implementing options exemplified throughout the figures accompanying this description are not necessarily intended to be adopted in the same combinations exemplified in the figures. One or more embodiments may thus adopt these (otherwise non-mandatory) options individually and/or in different combinations with respect to the combination exemplified in the accompanying figures.

Without prejudice to the underlying principles, the details and embodiments may vary, even significantly, with respect to what has been described by way of example only, without departing from the extent of protection. The extent of protection is defined by the annexed claims.

In one embodiment, a method includes producing (12, 14) an initial oscillating signal (V_{IN} (f₀)) having an initial frequency (f₀); applying signal amplification (16) to the initial oscillating signal (V_{IN} (f₀)), providing an output signal (V_{OUT} (f)) as a result, the output signal (V_{OUT} (f)) including a first harmonic component at the initial frequency (f₀) as well as a further signal component (V_{D}) at a further frequency (f₁); producing (30; 58, 59) at least one auxiliary oscillating signal (V_{AUX}) having an auxiliary frequency (f_{AUX}) equal to the further frequency (f₁); combining (32; 51) the initial oscillating signal (V_{IN} (f₀)) and the at least one auxiliary oscillating signal (V_{AUX}), producing a combined oscillating signal (V_{PD}(f₁)) as a result, and applying the signal amplification (16) to the combined oscillating signal (V_{PD}(f₁)), and in response to the at least one auxiliary oscillating signal (V_{AUX}) being an antiphase version of the second harmonic component (V_{D}), producing a combined output signal (V_{OUT}) exempt from the further signal component (V_{D}).

The further frequency (2f₀; Nf0; f₁) of the further signal component (V_{D}) is equal to an integer multiple, preferably twice, the initial frequency (f₀) so that the at least one auxiliary oscillating signal (V_{AUX}) has the auxiliary frequency (f_{AUX}) equal to the integer multiple, preferably twice, of the initial frequency (f₀).

The further frequency (2f₀; Nf0; f₁) of the further signal component (V_{D}) is equal to a linear combination of integer multiples of the initial frequency (f₀) so that the at least one auxiliary oscillating signal (V_{AUX}) has the auxiliary frequency (f_{AUX}) equal to a linear combination of integer multiples of the initial frequency (f₀).

The combined output signal (V_{OUT}) is exempt from the further signal component (V_{D}) in response to an auxiliary amplitude (|V_{AUX}|) of the at least one auxiliary oscillating signal (V_{AUX}) being equal to an amplitude of the further signal component (|V_{D}|) as well as in response to an auxiliary phase (Φ_{AUX}) of the at least one auxiliary oscillating signal (V_{AUX}) being equal and opposite to a phase of the further harmonic component (Φ_{D}).

The method includes iteratively adjusting (52, 53, 54, 55, 56, 57, 58, 59) the at least one auxiliary oscillating signal (V_{AUX}) from initial values until reaching the antiphase version of the further signal component (V_{D}).

Iteratively adjusting (52, 53, 54, 55, 56, 57, 58, 59) the at least one auxiliary oscillating signal (V_{AUX}) includes: initializing an auxiliary amplitude (|V_{AUX}|) of the at least one auxiliary oscillating signal (V_{AUX}) to an initial amplitude, preferably equal to zero; detecting (52, 53, 54, 55, 56, 57) the further harmonic component (V_{D}) in the output signal (V_{OUT}); setting an auxiliary amplitude (|V_{AUX}|) of the at least one auxiliary oscillating signal (V_{AUX}) to an initial amplitude, preferably equal half the amplification gain (A), initializing an auxiliary phase (Φ_{AUX}) of the at least one auxiliary oscillating signal (V_{AUX}(2f₀)) to an initial phase value, preferably equal to 45°; performing a comparison (55, 56) of the auxiliary signal (V_{AUX}) and the second harmonic signal (V_{D}), and iteratively adjusting (57) the auxiliary amplitude (|V_{AUX}) and/or the auxiliary phase (Φ_{AUX}) based on the comparison (55, 56) until reaching the antiphase version of the second harmonic component (V_{D}).

The method includes: applying down-conversion mixing (52, 53, 54) to the output signal (V_{OUT}) using a local oscillator signal (OSC) at a frequency equal to the further frequency (f₁) and a quadrature phase shifter (53) as well as applying low-pass filtering (53, 54), producing a first and a second mixed signal components in quadrature therebetween as a result, the first and second mixed signal components each including a respective DC component (I,Q); performing a first comparison (55) of the first mixed signal DC component (I) with a threshold (GND), providing a first logic signal (CS1) having a first, resp. second, logic value in response to the first mixed signal DC component (I) exceeding, resp. failing to exceed, the threshold (GND); performing a second comparison (56) of the second mixed signal DC component (Q) with the threshold (GND), providing a second logic signal (CS2) having a first, resp. second, logic value in response to the second mixed signal DC component (Q) exceeding, resp. failing to exceed, the threshold (GND); iteratively adjusting (57, 58, 59) the auxiliary amplitude (|V_{AUX}|) and/or the auxiliary phase (Φ_{AUX}) based on the comparison (55, 56) including adding or subtracting a fraction of the initial auxiliary amplitude and/or of the initial auxiliary phase, preferably via a successive-approximation controller (57), until reaching the antiphase version of the second harmonic component (V_{D}).

The method includes: producing (30; 58, 59) a plurality of auxiliary oscillating signals (V_{AUX1}, V_{AUX2}) each having an auxiliary frequency (f₁) equal to the further frequency (f₁); combining (32) the initial oscillating signal (V_{IN} (f₀)) and the plurality of auxiliary oscillating signals (V_{AUX1}, V_{AUX2}), producing a combined oscillating signal (V_{PD}(f₀, f₁)) as a result; applying the signal amplification (16) to the combined oscillating signal (V_{PD}(f₀, f₁)), and in response to a combination of one auxiliary oscillating signals in the plurality of auxiliary oscillating signals (V_{AUX1}, V_{AUX2}) being equal to an antiphase version of the second harmonic component (V_{D}), producing a combined output signal (V_{OUT}) exempt from the second harmonic component (V_{D}).

In one embodiment, a circuit (50) includes an initial oscillator circuit block (12, 14) configured to produce an initial oscillating signal (V_{IN} (f₀)) having an initial frequency (f₀); an amplification circuit block (16) coupled to the initial oscillator circuit block (12, 14) and configured to provide an output signal (V_{OUT} (f)) as a result of applying signal amplification to the initial oscillating signal (V_{IN} (f₀)), the output signal (V_{OUT} (f)) including a first harmonic component at the initial frequency (f₀) as well as a further harmonic component (V_{D}) at a further harmonic frequency (f₁); at least one auxiliary oscillator circuit block (58, 59) configured to produce at least one auxiliary oscillating signal (V_{AUX}(2f₀)) having an auxiliary frequency (f_{AUX}) equal to the further frequency (f₁); a combiner node (51) coupled to the initial oscillator circuit block (12, 14), to the at least one auxiliary oscillator circuit block (58, 59) and to the amplification circuit block (16), the combiner node (51) configured to combine (32) the initial oscillating signal (V_{IN} (f₀)) and the at least one auxiliary oscillating signal (V_{AUX}(f₁)), providing to the amplification circuit block (16) a combined oscillating signal as a result, wherein applying signal amplification (16) to the combined oscillating signal via the amplification circuit block (16) produces a combined output signal (V_{OUT}) exempt from the further harmonic component (V_{D}) in response to the at least one auxiliary oscillating signal (V_{AUX}(f₁)) being an antiphase version of the further harmonic component (V_{D}).

The combined output signal (V_{OUT}) is exempt from the further harmonic component (V_{D}) in response to an auxiliary amplitude (|V_{AUX}|) of the at least one auxiliary oscillating signal (V_{AUX}(f₁)) being equal to a further harmonic amplitude (|V_{D}|) of the further harmonic component (V_{D}) as well as of an auxiliary phase (Φ_{AUX}) of the at least one auxiliary oscillating signal (V_{AUX}(f₁)) being equal and opposite to a further harmonic phase (Φ_{D}) of the further harmonic component (V_{D}).

The circuit (50) includes signal processing circuitry (52, 53, 54, 55, 56, 57) configured to iteratively adjust the at least one auxiliary oscillating signal (V_{AUX}(f₁)) from initial values until reaching the antiphase version of the further harmonic component (V_{D}).

Said signal processing circuitry (52, 53, 54, 55, 56, 57) is selectively couplable (S1, S2) to the output signal (V_{OUT}) and is configured to: detect (52, 53, 54, 55, 56, 57) the further harmonic signal (V_{D}) in the output signal (V_{OUT}); initialize an auxiliary amplitude (|V_{AUX})) of the at least one auxiliary oscillating signal (V_{AUX}(f₁)) to an initial amplitude value, preferably equal to half an amplification gain (A) of the amplification circuit block (16); initialize an auxiliary phase (Φ_{AUX}) of the at least one auxiliary oscillating signal (V_{AUX}(f₁)) to an initial phase value, preferably equal to 45°; perform a comparison (55, 56) of the auxiliary signal (V_{AUX}) and the second harmonic signal (V_{D}), and drive the at least one auxiliary oscillator circuit block (58, 59) to iteratively adjust (57) the auxiliary amplitude (|V_{AUX}|) and/or the auxiliary phase (Φ_{AUX}) based on the comparison (55, 56) until reaching the antiphase version of the further harmonic component (V_{D}).

The circuit (50) includes: a down-conversion mixer circuit block (52, 53, 54) configured to apply down-conversion mixing to the output signal (V_{OUT}) using a local oscillator signal (OSC) at twice the initial frequency (f₀) and a quadrature phase shifter (53) as well as applying low-pass filtering (53, 54), producing a first and a second mixed signal components in quadrature therebetween as a result, the first and second mixed signal components each including a respective DC component (I,Q); a first comparator circuit block (55) coupled to the down-conversion mixer circuit block (52, 53, 54) and configured to perform a first comparison (55) of the first mixed signal DC component (I) with a threshold (GND), providing a first logic signal (CS1) having a first, resp. second, logic value in response to the first mixed signal DC component (I) exceeding, resp. failing to exceed, the threshold (GND); a second comparator circuit block (56) coupled to the down-conversion mixer circuit block (52, 53, 54) and configured to perform a second comparison (56) of the second mixed signal DC component (Q) with the threshold (GND), providing a second logic signal (CS2) having a first, resp. second, logic value in response to the second mixed signal DC component (Q) exceeding, resp. failing to exceed, the threshold (GND); control circuitry (57) configured to drive the at least one auxiliary oscillator circuit block (58, 59) to iteratively adjust the auxiliary amplitude (|V_{AUX}) and/or the auxiliary phase (Φ_{AUX}) based on the comparison (55, 56) including adding or subtracting a fraction of the initial auxiliary amplitude and/or of the initial auxiliary phase, preferably via a successive-approximation controller (57), until reaching the antiphase version of the further harmonic component (V_{D}).

Said at least one auxiliary oscillator circuit block (58, 59) includes a plurality of auxiliary oscillator circuit block (58, 59) configured to produce a plurality of auxiliary oscillating signals (V_{AUX1}, V_{AUX2}) each having an auxiliary frequency (f₁); the combiner node (51) is configured to combine (32) the initial oscillating signal (V_{IN} (f₀)) and the plurality of auxiliary oscillating signals (V_{AUX1}, V_{AUX2}), producing the combined oscillating signal (V_{PD}(f₀, 2f₀)) as a result, and wherein applying signal amplification (16) to the combined oscillating signal (V_{PD}(f₀, 2f₀)) via the amplification circuit block (16) produces a combined output signal (V_{OUT}) exempt from the further harmonic component (V_{D}) in response to a combination of one auxiliary oscillating signals in the plurality of auxiliary oscillating signals (V_{AUX1}, V_{AUX2}) being equal to an antiphase version of the further harmonic component (V_{D}).

A device (90) includes: at least one circuit (50); at least one ultrasound transducer circuit (LOAD, C, Probe) configured to be driven to produce ultrasound waves via the at least one circuit (50), preferably including a medical imaging device.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
producing an initial oscillating signal having an initial frequency;
applying signal amplification to the initial oscillating signal, providing an output signal as a result, the output signal including a first harmonic component at the initial frequency as well as a further signal component at a further frequency;
producing at least one auxiliary oscillating signal having an auxiliary frequency equal to the further frequency;
producing a combined oscillating signal by combining the initial oscillating signal and the at least one auxiliary oscillating signal;
applying the signal amplification to the combined oscillating signal; and
in response to the at least one auxiliary oscillating signal being an antiphase version of a second harmonic component, producing a combined output signal exempt from the further signal component.

2. The method of claim 1, wherein the further frequency of the further signal component is equal to an integer multiple, preferably twice, the initial frequency so that the at least one auxiliary oscillating signal has the auxiliary frequency equal to the integer multiple, preferably twice, of the initial frequency.

3. The method of claim 1, wherein the further frequency of the further signal component is equal to a linear combination of integer multiples of the initial frequency so that the at least one auxiliary oscillating signal has the auxiliary frequency equal to a linear combination of integer multiples of the initial frequency.

4. The method of claim 1, wherein the combined output signal is exempt from the further signal component in response to an auxiliary amplitude of the at least one auxiliary oscillating signal being equal to an amplitude of the further signal component as well as in response to an auxiliary phase of the at least one auxiliary oscillating signal being equal and opposite to a phase of the further harmonic component.

5. The method of claim 1, comprising iteratively adjusting the at least one auxiliary oscillating signal from initial values until reaching the antiphase version of the further signal component.

6. The method of claim 5, wherein iteratively adjusting the at least one auxiliary oscillating signal includes:
initializing an auxiliary amplitude of the at least one auxiliary oscillating signal to an initial amplitude equal to zero;
detecting the further harmonic component in the output signal;
setting an auxiliary amplitude of the at least one auxiliary oscillating signal to an initial amplitude, preferably equal half the amplification gain,
initializing an auxiliary phase of the at least one auxiliary oscillating signal to an initial phase value, preferably equal to 45°;
performing a comparison of the auxiliary signal and the second harmonic signal, and iteratively adjusting the auxiliary amplitude and/or the auxiliary phase based on the comparison until reaching the antiphase version of the second harmonic component.

7. The method of claim 5, comprising:
applying down-conversion mixing to the output signal using a local oscillator signal at a frequency equal to the further frequency and a quadrature phase shifter as well as applying low-pass filtering, producing a first and a second mixed signal components in quadrature therebetween as a result, the first and second mixed signal components each including a respective DC component;
performing a first comparison of the first mixed signal DC component with a threshold, providing a first logic signal having a first, resp. second, logic value in response to the first mixed signal DC component exceeding, resp. failing to exceed, the threshold;
performing a second comparison of the second mixed signal DC component with the threshold, providing a second logic signal having a first, resp. second, logic value in response to the second mixed signal DC component exceeding, resp. failing to exceed, the threshold;
iteratively adjusting the auxiliary amplitude and/or the auxiliary phase based on the comparison including adding or subtracting a fraction of the initial auxiliary amplitude and/or of the initial auxiliary phase, preferably via a successive-approximation controller, until reaching the antiphase version of the second harmonic component.

8. The method of claim 1, comprising:
producing a plurality of auxiliary oscillating signals each having an auxiliary frequency equal to the further frequency;
combining the initial oscillating signal and the plurality of auxiliary oscillating signals, producing a combined oscillating signal as a result;
applying the signal amplification to the combined oscillating signal, and
in response to a combination of one auxiliary oscillating signals in the plurality of auxiliary oscillating signals being equal to an antiphase version of the second harmonic component, producing a combined output signal exempt from the second harmonic component.

9. A circuit, comprising:
an initial oscillator circuit block configured to produce an initial oscillating signal having an initial frequency;
an amplification circuit block coupled to the initial oscillator circuit block and configured to provide an output signal as a result of applying signal amplification to the initial oscillating signal, the output signal including a first harmonic component at the initial frequency as well as a further harmonic component at a further harmonic frequency;
at least one auxiliary oscillator circuit block configured to produce at least one auxiliary oscillating signal having an auxiliary frequency equal to the further frequency;
a combiner node coupled to the initial oscillator circuit block, to the at least one auxiliary oscillator circuit block and to the amplification circuit block, the combiner node configured to combine the initial oscillating signal and the at least one auxiliary oscillating signal, providing to the amplification circuit block a combined oscillating signal as a result,
wherein applying signal amplification to the combined oscillating signal via the amplification circuit block produces a combined output signal exempt from the further harmonic component in response to the at least one auxiliary oscillating signal being an antiphase version of the further harmonic component.

10. The circuit of claim 9, wherein the combined output signal is exempt from the further harmonic component in response to an auxiliary amplitude of the at least one auxiliary oscillating signal being equal to a further harmonic amplitude of the further harmonic component as well as of an auxiliary phase of the at least one auxiliary oscillating signal being equal and opposite to a further harmonic phase of the further harmonic component.

11. The circuit of claim 9, comprising signal processing circuitry configured to iteratively adjust the at least one auxiliary oscillating signal from initial values until reaching the antiphase version of the further harmonic component.

12. The circuit of claim 10, wherein the signal processing circuitry is selectively couplable to the output signal and is configured to:
detect the further harmonic signal in the output signal;
initialize an auxiliary amplitude of the at least one auxiliary oscillating signal to an initial amplitude value, preferably equal to half an amplification gain of the amplification circuit block;
initialize an auxiliary phase of the at least one auxiliary oscillating signal to an initial phase value, preferably equal to 45°;
perform a comparison of the auxiliary signal and the second harmonic signal, and
drive the at least one auxiliary oscillator circuit block to iteratively adjust the auxiliary amplitude and/or the auxiliary phase based on the comparison until reaching the antiphase version of the further harmonic component.

13. The circuit of claim 9, comprising:
a down-conversion mixer circuit block configured to apply down-conversion mixing to the output signal using a local oscillator signal at twice the initial frequency and a quadrature phase shifter as well as applying low-pass filtering, producing a first and a second mixed signal components in quadrature therebetween as a result, the first and second mixed signal components each including a respective DC component;
a first comparator circuit block coupled to the down-conversion mixer circuit block and configured to perform a first comparison of the first mixed signal DC component with a threshold, providing a first logic signal having a first, resp. second, logic value in response to the first mixed signal DC component exceeding, resp. failing to exceed, the threshold;
a second comparator circuit block coupled to the down-conversion mixer circuit block and configured to perform a second comparison of the second mixed signal DC component with the threshold, providing a second logic signal having a first, resp. second, logic value in response to the second mixed signal DC component exceeding, resp. failing to exceed, the threshold;
control circuitry configured to drive the at least one auxiliary oscillator circuit block to iteratively adjust the auxiliary amplitude and/or the auxiliary phase based on the comparison including adding or subtracting a fraction of the initial auxiliary amplitude and/or of the initial auxiliary phase, preferably via a successive-approximation controller, until reaching the antiphase version of the further harmonic component.

14. The circuit of claim 9, wherein:
said at least one auxiliary oscillator circuit block includes a plurality of auxiliary oscillator circuit block configured to produce a plurality of auxiliary oscillating signals each having an auxiliary frequency;
the combiner node is configured to combine the initial oscillating signal and the plurality of auxiliary oscillating signals, producing the combined oscillating signal as a result, and
wherein applying signal amplification to the combined oscillating signal via the amplification circuit block produces a combined output signal exempt from the further harmonic component in response to a combination of one auxiliary oscillating signals in the plurality of auxiliary oscillating signals being equal to an antiphase version of the further harmonic component.

15. A method, comprising:
generating a first oscillating signal having a first frequency;
generating, with a compensation circuit, a second oscillating signal having a second frequency corresponding to a harmonic of the first frequency;
generating a combined input signal by combining first oscillating signal with the second oscillating signal;
providing the combined input signal to an amplifier;
generating, with the amplifier, an output signal by amplifying the input signal;
providing the output signal to the compensation circuit in a feedback arrangement; and
reducing, in the output signal, a harmonic component of the output signal adjusting the second oscillating signal with the compensation circuit based on the output signal, the harmonic component having the second frequency.

16. The method of claim 15, wherein generating the second oscillating signal includes:
generating a first auxiliary signal having the second frequency; and
generating a second auxiliary signal having the second frequency out of phase with the first auxiliary signal.

17. The method of claim 16, wherein the second auxiliary signal is 90° out of phase with the first auxiliary signal.

18. The method of claim 16, further comprising:
generating, with a first comparator of the compensation circuit, a first control signal based on a first phase component of the harmonic component of the output signal; and
generating, with a second comparator of the compensation circuit, a second control signal based on a second phase component of the harmonic component of the output signal.

19. The method of claim 18, further comprising controlling, with the control circuit, generation of the first and second auxiliary signals based on the first control signal and the second control signal.

20. The method of claim 19, further comprising:
generating the first auxiliary signal with a first auxiliary generator of the compensation circuit under control of the control circuit; and
generating the second auxiliary signal with a second auxiliary generator of the compensation circuit under control of the control circuit.
